(19) United States
(12) Patent Application Publication
(10) Pub. No.: US 2007/0090474 A1
(43) Pub. Date: Apr. 26, 2007

(54) MEMS device and method of fabrication

(76) Inventors: Gary G. Li, Gilbert, AZ (US); Bishnu Gogoi, Scottsdale, AZ (US); Hemant D. Desai, Gilbert, AZ (US); Jonathan Hale Hammond, Oak Ridge, NC (US); Bernard Diem, Echirolles (FR)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/222,547

(22) Filed: Sep. 8, 2005

(51) Int. Cl. H01L 29/82

(52) U.S. Cl. 257/414

(57) ABSTRACT

A MEMS device and method of fabrication including a plurality of structural tie bars for added structural integrity. The MEMS device includes an active layer and a substrate having an insulating material formed therebetween, first and second pluralities of stationary electrodes and a plurality of moveable electrodes in the active layer. A plurality of interconnects are electrically coupled to a second surface of each of the first and second pluralities of stationary electrodes. A plurality of anchors fixedly attach a first surface of each of the first and second pluralities of stationary electrodes to the substrate. A first structural tie bar couples a second surface of each of the first plurality of stationary electrodes and a second structural tie bar couples a second surface of each of the second plurality of stationary electrodes.

### FIELD OF THE INVENTION

The present invention generally relates to MEMS devices and methods for fabricating MEMS devices, and more particularly relates to improving the structural integrity of MEMS devices.

### BACKGROUND OF THE INVENTION

One type of high aspect ratio micro-electromechanical system (MEMS) device, also known as a HARMEMS device, is formed as a semiconductor-on-insulator (SOI) based sensor device on a wafer substrate. During fabrication, the MEMS device, and more particularly the stationary sensor electrodes, are anchored to the wafer substrate through an oxide material. This oxide material anchor offers significant cost reduction over the present HARMEMS anchor approaches. While this significant cost reduction has been achieved with the use of the oxide material as an anchor, these oxide anchors are less than ideal. In high aspect ratio MEMS devices, the electrode anchors formed of the oxide material are often the weakest mechanical components. The oxide material has a low fracture limit and is prone to breakage during sensor shipping and handling, typically due to dropping and/or severe impact. Thus, there is a need to improve the design of the MEMS devices so as to enable these electrodes to survive the extreme mechanical loadings associated with dropping and/or severe impact.

Accordingly, it is desirable to provide for high quality, reliable MEMS device in which the ability to withstand mechanical stress is improved. In addition, it is desired to provide for a MEMS device in which structural integrity of the sensing structure is preserved when the oxide anchor connection fails.

### BRIEF DESCRIPTION OF THE DRAWINGS

The present invention will hereinafter be described in conjunction with the following drawing figures, wherein like numerals denote like elements, and wherein

FIG. 1 illustrates schematically, in top view, a portion of a MEMS device in accordance with an exemplary embodiment of the invention;

FIGS. 2-7 illustrate schematically, in cross section, method steps in accordance with an exemplary embodiment of the invention for fabricating the sensor device of FIG. 1; and

FIG. 8 illustrates schematically a three-dimensional schematic view of a portion of a MEMS device in accordance with an exemplary embodiment of the invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

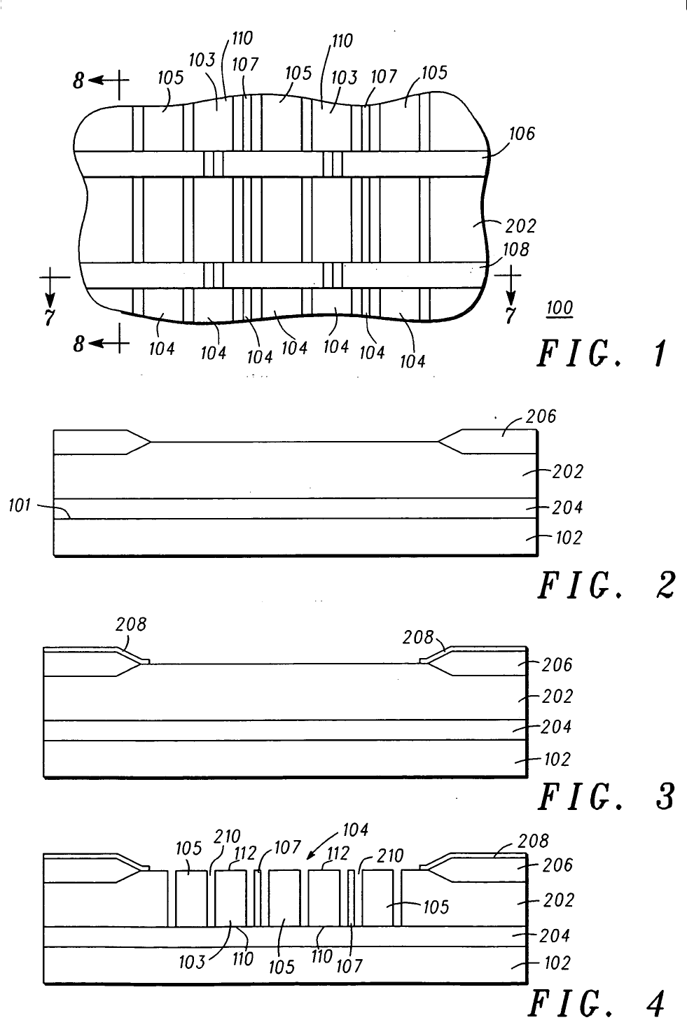

Referring now to FIG. 1, illustrated is a top view of a portion of a sensor device 100 in accordance with an embodiment of the invention. Sensor device 100 is a standard MEMS device and includes a substrate (described below), having a plurality of interdigitated electrodes 104 formed upon a first surface. Interdigitated electrodes 104 are formed of a silicon material and include a plurality of stationary electrode structures, i.e. a first plurality of stationary electrodes 103, a second plurality of stationary electrodes 105, and a plurality of moveable electrode structures 107. Moveable electrode structures 107 are configured to interleave with stationary electrodes 103 and 105. A first surface (illustrated below) of each of the first and second plurality of stationary electrodes 103 and 105 are anchored, or fixedly attached, to the substrate via a plurality of oxide anchors (described below). First and second plurality of stationary electrodes 103 and 105 are in electrical communication with an external electrical power source via a plurality of polysilicon or metal interconnects 106 (only one of which is shown in FIG. 1). A plurality of structural stiffening mechanisms 108 (only one of which is shown in FIG. 1), herein also referred to as structural tie bars, provide external structural coupling and reinforcement of first plurality of stationary electrodes 103 and second plurality of stationary electrodes 105. More particularly, a first plurality of structural tie bars couple the first plurality of stationary electrodes 103, and a second plurality of structural tie bars couple the second plurality of stationary electrodes 105. Structural tie bar 108 provides mechanical support to preserve the structural integrity of the sensing structure even if some of the plurality of oxide anchors fail.

As illustrated in FIG. 1, structural tie bar 108 structurally couples the first plurality of stationary electrodes 103. The addition of a plurality of structural tie bars, similar to structural tie bar 108, to device 100, may increase the structural stiffness of device 100 by greater than 10×. At the same time, additional parasitic capacitance remains negligible. The plurality of structural tie bars, similar to structural tie bar 108, are formed in a symmetric manner about an axis parallel to structural tie bar 108, and substantially evenly distributed across device 100 to preserve the overall structural symmetry of device 100. This symmetrical design reduces the thermally induced offset of the output.

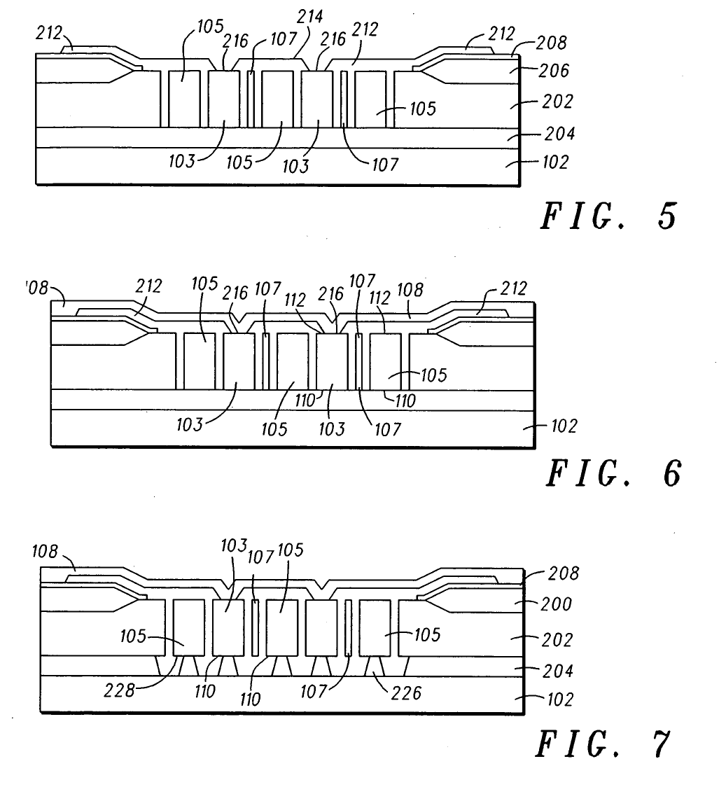

FIGS. 2-7 illustrate method steps for manufacturing a semiconductor device such as sensor device 100, in accordance with one embodiment of the invention. It should be understood that the elements in FIGS. 2-7 that have been previously described with regard to FIG. 1, will be numbered the same.

Referring to FIG. 2, the process begins with providing a device quality active layer 202 (e.g. a silicon active layer) and a substrate 102 (e.g. a silicon handle wafer). An insulating material (e.g. silicon oxide or silicon nitride) is formed on first surface 101 of substrate 102. In this particular embodiment, an insulating oxide material 204 is formed on first surface 101. Active layer 202 is bonded to substrate 102, wherein insulating oxide material 204 is positioned there between as in typical SOI device fabrication. In an alternative embodiment, active layer 202 is grown on a first surface of insulating oxide material 204 as an epitaxial silicon layer. A field oxide layer 206 is grown over a portion of active layer 202 to provide an area to build a sensor structure and to reduce parasitic capacitance in device 100. As illustrated in FIG. 2, a gentle slope in field oxide layer 206 forms a bird's beak structure and provides step coverage of photoresists in subsequent processing steps. Field oxide layer 206 is formed using a local oxidation of silicon (LOCOS) technique common to MOS silicon technology. Field oxide layer 206 may be formed of a thermally grown SiO_{2.}

FIG. 3 illustrates an isolation layer 208 formed on a surface of field oxide layer 206 to protect field oxide layer 206 from a subsequent release etch step. In one embodiment, isolation layer 208 is a low stress, silicon rich material, such as silicon nitride. In other embodiments, isolation layer 208 is a silicon carbide material, or a multilayer formed of alternating layers of nitride and polysilicon. In a preferred embodiment, insulation layer 208 overlaps active layer 202. In one embodiment isolation layer 208 is formed by dipping device structure 100 in a dilute hydrofluoric (HF) dip to reduce native oxide growth. Next, low pressure chemical vapor deposition (LPCVD) is used to deposit the isolation material which forms isolation layer 208 to a thickness in a range of approximately 0.3 to 0.8 μm. Photolithography processing steps are utilized to provide for a completed patterned isolation layer 208.

After patterned isolation layer 208 is formed, a plurality of mechanical structures are formed in active layer 202 as illustrated in FIG. 4. In one embodiment, the active structures include plurality of electrodes 104 formed in active layer 202 by etching, such as by deep reactive ion etching (DRIE). Additional active structures formed in active layer 202 may include spring suspensions, seismic masses, anchor islands, and lateral stops. To define plurality of electrodes 104, a plurality of trenches 210 are formed in active layer 202 using standard etch processing. Insulating oxide material 204 acts as an etch stop layer during the fabrication of electrodes 104. FIG. 4 illustrates the resultant first plurality of stationary electrodes 103, second plurality of stationary electrodes 105, and plurality of moveable electrodes 107 subsequent to the step of removing a photoresist used in forming trenches 210. Each of the first plurality of stationary electrodes 103 and second plurality of stationary electrodes 105 has a first surface 110 and a second surface 112. In a preferred embodiment, each of the first plurality of stationary electrodes 103 and second plurality of stationary electrodes 105 have a width of approximately 16 microns. Moveable electrodes 107 each have width of approximately 2.5 microns. Depending on specific design requirements, the width of stationary electrodes 103 and 105 and moveable electrodes 107 may vary greatly.

A trench refill step is performed after trenches 210 are formed. FIG. 5 illustrates one embodiment wherein a layer of fill material, such as phosphosilicate glass (PSG), is deposited and reflowed to fill trenches 210. This refill step results in a layer 212 of fill material that includes a planar surface 214 at the top of the device area. Layer 212 of fill material provides complete sealing of trenches 210 in the device area. A plurality of contact areas 216 for plurality of electrodes 104 are defined by patterning layer 212 of fill material. In an alternative embodiment, layer 212 of fill material may partially fill trenches 210.

Thereafter, and with reference to FIG. 6, a plurality of structural tie bars 108 (only one of which is shown in FIG. 6) are formed to provide structural stiffness to device 100. Structural tie bars 108 may be formed of a doped polysilicon material or a metal (e.g. aluminum, aluminum silicon, aluminum silicon copper, or any other conductive alloy composition as known in the art). In one embodiment, structural tie bar 108 is fabricated as bridge structure whereby a blanket layer of polysilicon material having a thickness in a range of 1.5-2.5 μm is deposited using LPCVD over layer 212 of fill material. Next, a layer of photoresist (not shown) is deposited to a thickness sufficient for step coverage and to withstand a subsequent etch, such as a reactive ion etch (RIE). Photolithography steps pattern structural tie bar 108 resulting in a feature line of >4 μm. Layer 212 of fill material and isolation layer 208 serve as etch stop layers during this etch step to pattern structural tie bar 108.

FIG. 6 illustrates structural tie bar 108 fabricated and coupled to second surface 112 of each first plurality of stationary electrodes 103. Additional tie bars (not shown) are fabricated and coupled to second surface 112 of each second plurality of stationary electrodes 105.

Simultaneous to the fabrication of structural tie bar 108, a plurality of interconnects, similar to interconnect 106 (FIG. 1) are formed in generally the same manner as structural tie bar 108. Interconnects 106 may be formed of a doped polysilicon material or a metal (e.g. aluminum, aluminum silicon, aluminum silicon copper, or any other conductive alloy composition as known in the art). In one embodiment, interconnect 106 is fabricated as bridge structure whereby a blanket layer of polysilicon material having a thickness in a range of 1.5-2.5 μm is deposited using LPCVD over layer 212 of fill material to provide low contact resistance to the active electrodes. The polysilicon material is made conductive by doping during deposition or by providing a dopant source such as ion implantation subsequent to deposition and then driving in the dopants using a high temperature anneal step. An etch step (e.g. reactive ion etch (RIE)) is performed to define the plurality of interconnects. Layer 212 of fill material and isolation layer 208 serve as etch stop layers during this etch step to pattern interconnect 106.

In an alternative embodiment, interconnect 106, and structural tie bar 108 may be formed in separate steps. As illustrated in FIG. 1, structural tie bar 108 is fabricated to couple second surface 112 of at least two of the first plurality of stationary electrodes 103. Additional structural tie bars (not shown) will be fabricated to couple second surface 112 of at least two of the second plurality of stationary electrodes 105. Moveable electrode structures 107 are not in contact with structural tie bar 108 to maintain the ability to move in response to a change in acceleration or other types of external force.

FIG. 7 illustrates device 100 wherein layer 212 of fill material is removed and oxide material 204 is partially removed to define a plurality of oxide anchors 226. In one embodiment, a release etch step is performed using HF chemistry to etch layer 212 of fill material which is a sacrificial layer. Next, a timed dry etch, such as a dry HF chemistry vapor etch, is performed to etch insulating oxide material 204 and release plurality of moveable electrodes 107 as a result of etching away that portion of insulating oxide material 204 in contact with moveable electrodes 107. Layer 212 of fill material is completely removed during the initial etch step to prevent residue formation during the subsequent dry etch. Sufficient overetch time is provided to account for non-uniform release etch across the wafer during the dry etch to form oxide anchors 226.

Oxide anchors 226 extend from first surface 110 of each of the first plurality of stationary electrodes 103 and each of the second plurality of stationary electrodes 105 for the purpose of fixedly attaching or anchoring first surface 110 of each of the first plurality of stationary electrodes 103 and first surface 110 of each of the second plurality of stationary electrodes 105 to substrate 102. This structural coupling of first plurality of stationary electrodes 103 and second plurality of stationary electrodes 105 on first surface 110 provides additional structural stability to the overall device structure. In a preferred embodiment, each of the first plurality of stationary electrodes 103 and each of the second plurality of stationary electrodes 105 have an undercut 228 of approximately 4 microns formed symmetrically on either side of each of the pluralities of stationary electrodes 103 and 105. The remaining insulating oxide material 204, that forms oxide anchors 226, has a width of approximately 4 to 6 microns that is in contact with each of the first plurality of stationary electrodes 103 and second plurality of stationary electrodes 105. In one embodiment, plurality of moveable electrodes 107 are also undercut approximately 4 microns in the same timed etch step, resulting in the complete removal of insulating oxide material 204 from beneath each of the plurality of moveable electrodes 107. This time based etch step is not uniform due to the wafer bond between the substrate 102 and the active layer 202. Accordingly, the amount of undercut 228 may vary from electrode-to-electrode. This variance in undercut typically results in a sensor device that requires additional structural stiffness to withstand subsequent handling, testing, and shipping. The inclusion of a structural stiffening mechanism, such as a plurality of structural tie bars formed generally similar to structural tie bar 108 (FIG. 1) fulfills this requirement.

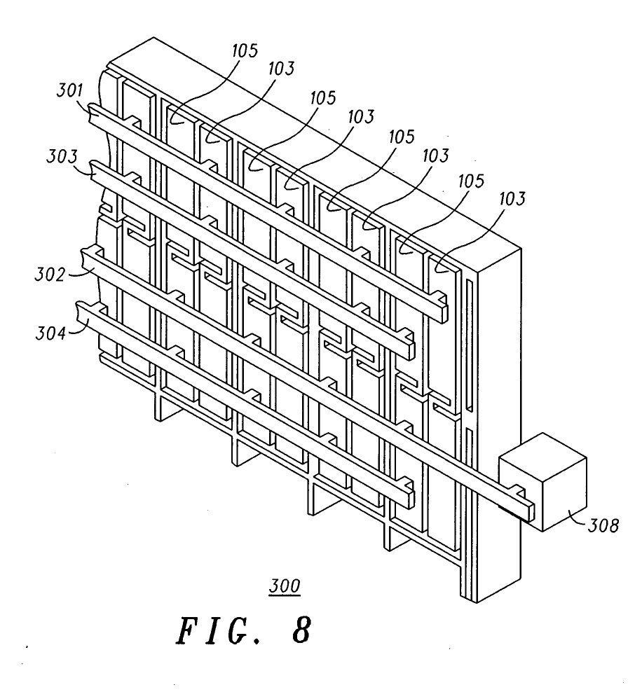

FIG. 8 illustrates a three-dimensional schematic view of a portion of a MEMS device 300 generally similar to sensor device 100 of FIG. 1. MEMS device 300 includes a first plurality of interconnects 301 (only one of which is shown in FIG. 8) and a second plurality of interconnects 302 (only one of which is shown in FIG. 8), each generally similar to polysilicon interconnect 106 of FIGS. 1-7. MEMS device 300 is further includes a first plurality of structural tie bars 303 (only one of which is shown in FIG. 8) and a second plurality of structural tie bars 304 (only one of which is shown in FIG. 8), each generally similar to structural tie bar 108 of FIGS. 1-7. As illustrated, first plurality of interconnects 301 are electrically coupled to first plurality of stationary electrodes 103, second plurality of interconnects 302 are electrically coupled to second plurality of stationary electrodes 105, first plurality of structural tie bars 303 are coupled to first plurality of stationary electrodes 103, and second plurality of structural tie bars 304 are coupled to first plurality of stationary electrodes 105, as previously detailed. First plurality of structural tie bars 303 and second plurality of structural tie bars 304 are formed generally symmetric about an axis parallel to first plurality of structural tie bars 303 and second plurality of structural tie bars 304 and substantially evenly distributed across the MEMS device 300 to preserve overall structural symmetry and lower thermally induced offset. Each individual interconnect of the first plurality of interconnects 301 and second plurality of interconnects 302 is in electrical communication with a bond pad 308, wherein a plurality of bond pads (only one of which is shown in FIG. 8), similar to bond pad 308, are formed about a perimeter of MEMS device 300.

Provided is a MEMS device of the type which includes an active layer, a substrate, and an insulating material therebetween, first and second pluralities of stationary electrodes and a plurality of moveable electrodes formed in the active layer, and a plurality of anchors fixedly attaching a first surface of each of the first and second pluralities of stationary electrodes to the substrate, the MEMS device comprising: a first structural tie bar coupled to a second surface of at least two of the first plurality of stationary electrodes; and a second structural tie bar coupled to a second surface of at least two of the second plurality of stationary electrodes. The device may be a high aspect ratio MEMS sensor device. The first and second structural tie bars may comprise polysilicon. The first and second structural tie bars may be symmetric about an axis parallel to the first and second structural tie bars and substantially evenly distributed across the MEMS device.

Additionally, provided is a method of fabricating a MEMS device of the type that includes an active layer, a substrate, and an insulating material formed therebetween, first and second pluralities of stationary electrodes and a plurality of moveable electrodes in the active layer, a fill material deposited between the first and second pluralities of stationary electrodes and the plurality of moveable electrodes, a layer of conductive material deposited over the first and second pluralities of stationary electrodes and the plurality of moveable electrodes wherein the method comprises: etching the layer of conductive material to define a first interconnect electrically coupled to the first plurality of stationary electrodes and a second interconnect electrically coupled to the second plurality of stationary electrodes; etching the layer of conductive material to define a first structural tie bar coupled to a second surface of each of the first plurality of stationary electrodes and a second structural tie bar coupled to a second surface of each of the second plurality of stationary electrodes; removing the layer of fill material; etching the insulating material to define a plurality of anchors fixedly attaching a first surface of each of the first and second pluralities of stationary electrodes to the substrate. The MEMS device may be a high aspect ratio MEMS sensor device. The step of etching the layer of conductive material may include a reactive ion etch (RIE). The step of removing the layer of fill material may include etching the fill material. The step of removing the layer of fill material may include a hydrofluoric (HF) vapor etch. The step of etching the insulating material may include a hydrofluoric (HF) vapor etch. The first and second structural tie bars may be symmetric about an axis parallel to the first and second structural tie bars and substantially evenly distributed across the MEMS device.

Finally, provided is a MEMS device comprising: a substrate; an insulating layer on the substrate; an active layer on the insulating layer; a plurality of sensor electrodes in the active layer having a first surface and a second surface, at least one of the plurality of sensor electrodes further having a contact area formed on the second surface; a plurality of interconnects each electrically coupled to at least one of the plurality of sensor electrodes; a plurality of structural tie bars each coupled to the first surface of at least two sensor electrodes; and a plurality of anchors fixedly attaching the second surface of at least a portion of the plurality of sensor electrodes to the substrate. The device may be formed as a high aspect ratio MEMS sensor device. The substrate may comprise silicon. The plurality of sensor electrodes may be comprised of first and second pluralities of stationary electrodes and a plurality of moveable electrodes. The plurality of structural tie bars may comprise a first plurality of structural tie bars coupled to the first plurality of stationary electrodes and a second plurality of structural tie bars coupled to the second plurality of stationary electrodes. The plurality of anchors fixedly attach the first and second pluralities of stationary electrodes to the substrate. The plurality of interconnects may comprise polysilicon. The plurality of structural tie bars may comprise polysilicon. The plurality of structural tie bars may be symmetric about an axis parallel to the plurality of structural tie bars and substantially evenly distributed across the MEMS device.

While at least one exemplary embodiment and method of fabrication has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A MEMS device of the type which includes an active layer, a substrate, and an insulating material therebetween, first and second pluralities of stationary electrodes and a plurality of moveable electrodes formed in the active layer, and a plurality of anchors fixedly attaching a first surface of each of the first and second pluralities of stationary electrodes to the substrate, the MEMS device comprising:
a first structural tie bar coupled to a second surface of at least two of the first plurality of stationary electrodes; and
a second structural tie bar coupled to a second surface of at least two of the second plurality of stationary electrodes.

2. The device of claim 1 wherein the device is a high aspect ratio MEMS sensor device.

3. The device of claim 1 wherein the first and second structural tie bars comprise polysilicon.

4. The device of claim 1 wherein the first and second structural tie bars are symmetric about an axis parallel to the first and second structural tie bars and substantially evenly distributed across the MEMS device.

5. A method of fabricating a MEMS device of the type that includes an active layer, a substrate, and an insulating material formed therebetween, first and second pluralities of stationary electrodes and a plurality of moveable electrodes in the active layer, a fill material deposited between the first and second pluralities of stationary electrodes and the plurality of moveable electrodes, a layer of conductive material deposited over the first and second pluralities of stationary electrodes and the plurality of moveable electrodes wherein the method comprises:
etching the layer of conductive material to define a first interconnect electrically coupled to the first plurality of stationary electrodes and a second interconnect electrically coupled to the second plurality of stationary electrodes;
etching the layer of conductive material to define a first structural tie bar coupled to a second surface of each of the first plurality of stationary electrodes and a second structural tie bar coupled to a second surface of each of the second plurality of stationary electrodes;
removing the layer of fill material;
etching the insulating material to define a plurality of anchors fixedly attaching a first surface of each of the first and second pluralities of stationary electrodes to the substrate.

6. The method of claim 5 wherein the MEMS device is a high aspect ratio MEMS sensor device.

7. The method of claim 5 wherein the step of etching the layer of conductive material includes a reactive ion etch (RIE).

8. The method of claim 5 wherein the step of removing the layer of fill material includes etching the fill material.

9. The method of claim 8 wherein the step of removing the layer of fill material includes a hydrofluoric (HF) vapor etch.

10. The method of claim 5 wherein the step of etching the insulating material includes a hydrofluoric (HF) vapor etch.

11. The method of claim 5 wherein the first and second structural tie bars are symmetric about an axis parallel to the first and second structural tie bars and substantially evenly distributed across the MEMS device.

12. A MEMS device comprising:
a substrate;
an insulating layer on the substrate;
an active layer on the insulating layer;
a plurality of sensor electrodes in the active layer having a first surface and a second surface, at least one of the plurality of sensor electrodes further having a contact area formed on the second surface;
a plurality of interconnects each electrically coupled to at least one of the plurality of sensor electrodes;
a plurality of structural tie bars each coupled to the first surface of at least two sensor electrodes; and
a plurality of anchors fixedly attaching the second surface of at least a portion of the plurality of sensor electrodes to the substrate.

13. The device of claim 12 wherein the device is formed as a high aspect ratio MEMS sensor device.

14. The device of claim 12 wherein the substrate comprises silicon.

15. The device of claim 12 wherein the plurality of sensor electrodes are comprised of first and second pluralities of stationary electrodes and a plurality of moveable electrodes.

16. The device of claim 15 wherein the plurality of structural tie bars comprise a first plurality of structural tie bars coupled to the first plurality of stationary electrodes and a second plurality of structural tie bars coupled to the second plurality of stationary electrodes.

17. The device of claim 15 wherein the plurality of anchors fixedly attach the first and second pluralities of stationary electrodes to the substrate.

18. The device of claim 12 wherein the plurality of interconnects comprise polysilicon.

19. The device of claim 12 wherein the plurality of structural tie bars comprise polysilicon.

20. The device of claim 12 wherein the plurality of structural tie bars are symmetric about an axis parallel to the plurality of structural tie bars and substantially evenly distributed across the MEMS device.
